(19) United States
(12) Patent Application Publication
(10) Pub. No.: US 2022/0223222 A1
(43) Pub. Date: Jul. 14, 2022

(54) POST PACKAGE REPAIRING METHOD AND APPARATUS FOR MEMORY, STORAGE MEDIUM, AND ELECTRONIC DEVICE

(71) Applicant: CHANGXIN MEMORY TECHNOLOGIES, INC., Hefei City (CN)

(72) Inventors: Zhenlin QU, Hefei (CN); Wenxi ZHANG, Hefei (CN)

(21) Appl. No.: 17/669,538

(22) Filed: Feb. 11, 2022

Related U.S. Application Data
(63) Continuation of application No. PCT/CN2021/110385, filed on Aug. 3, 2021.

(30) Foreign Application Priority Data
Jan. 12, 2021 (CN) 202110033504.3

(51) Int. Cl. G11C 29/42; G11C 29/44; G11C 29/18; G11C 29/00

(52) U.S. Cl. CPC G11C 29/42; G11C 29/4401; G11C 2029/4402; G11C 29/785; G11C 29/18

(57) ABSTRACT

A post package repairing method for a memory includes: during a memory test, writing failure information of the memory into the memory, the failure information including failure addresses; after a device is powered on, reading the failure addresses from the memory, and determining a number of failed lines where the failure addresses are located; when the number of the failed lines is less than or equal to a number of redundant lines, repairing the failed lines by using the redundant lines; and when the number of the failed lines is greater than the number of the redundant lines, loading the failure information into a register.

### CROSS-REFERENCE TO RELATED APPLICATIONS

This application is a continuation of International Application No. PCT/CN2021/110385, filed on Aug. 3, 2021, which claims priority to Chinese Patent Application No. 202110033504.3, filed on Jan. 12, 2021. The disclosures of International Application No. PCT/CN2021/110385 and Chinese Patent Application No. 202110033504.3 are hereby incorporated by reference in their entireties.

### TECHNICAL FIELD

The present disclosure relates to the technical field of integrated circuits, and particularly relates to a post package repairing method and apparatus for a memory, a computer-readable storage medium, and an electronic device.

### BACKGROUND

A computer system is generally composed of five parts: a processor, a memory, an input device, an output device and a bus. The memory is used to store the instructions and data required by the processor to run. The memory is generally realized by a Dynamic Random Access Memory (DRAM) of a semiconductor process.

The DRAM usually includes one or more memory cell arrays, and each of the memory cell arrays includes memory cells arranged in a matrix of rows and columns. The DRAM usually further includes redundant memory cells which can be used to functionally replace failure memory cells in the memory cell array.

However, after packaging, the redundant memory cells available in each of bank groups are limited, so that all repair operations of the failure memory cells cannot be realized.

### SUMMARY

According to one aspect of the present disclosure, a post package repairing method for a memory is provided. The method includes: during a memory test, failure information of the memory is written into Serial the memory, and the failure information includes failure addresses; after a device is powered on, the failure addresses are read from the memory, and a number of failed lines where the failure addresses are located is determined; when the number of the failed lines is less than or equal to a number of redundant lines, the failed lines are repaired by using the redundant lines; and when the number of the failed lines is greater than the number of the redundant lines, the failure information is loaded into a register.

According to one aspect of the present disclosure, a post package repairing apparatus for a memory is provided. The apparatus includes: a writing circuit configured to write failure information of the memory into the memory during a memory test, the failure information including failure addresses; a reading circuit configured to read the failure addresses from the memory and determine a number of failed lines where the failure addresses are located after a device is powered on; a first repairing circuit configured to repair the failed lines by using the redundant lines when the number of the failed lines is less than or equal to a number of redundant lines; and a second repairing circuit configured to load the failure information into a register when the number of the failed lines is greater than the number of the redundant lines.

According to one aspect of the present disclosure, a non-transitory computer-readable storage medium is provided. The storage medium has stored thereon computer-executable instructions that, when executed by a processor, cause the processor to perform operations of: during a memory test, writing failure information of the memory into the memory, the failure information comprising failure addresses; after a device is powered on, reading the failure addresses from the memory, and determining a number of failed lines where the failure addresses are located; when the number of the failed lines is less than or equal to a number of redundant lines, repairing the failed lines by using the redundant lines; and when the number of the failed lines is greater than the number of the redundant lines, loading the failure information into a register.

It should be understood that the above general description and the following detailed description are exemplary and explanatory only, and are not intended to limit the present disclosure.

### BRIEF DESCRIPTION OF THE DRAWINGS

The drawings herein are incorporated in and constitute a part of the specification, illustrating embodiments consistent with the present disclosure, and explaining the principles of the present disclosure together with the specification. Apparently, the drawings in the following description are only some embodiments of the present disclosure. Those of ordinary skill in the art can further obtain other drawings based on these drawings without creative work.

FIG. 1 schematically shows a block diagram of a post package repairing system for a memory according to an exemplary embodiment of the present disclosure.

FIG. 2 schematically shows a schematic structural diagram of an integrated circuit according to an exemplary embodiment of the present disclosure.

FIG. 3 schematically shows a flowchart of steps of a post package repairing method for a memory according to an exemplary embodiment of the present disclosure.

FIG. 4 schematically shows a flowchart of a post package repairing process according to an exemplary embodiment of the present disclosure.

FIG. 5 schematically shows a block diagram of a post package repairing apparatus for a memory according to an exemplary embodiment of the present disclosure.

FIG. 6 schematically shows a schematic module diagram of an electronic device according to an exemplary embodiment of the present disclosure.

### DETAILED DESCRIPTION

Exemplary embodiments will now be described more fully with reference to the accompanying drawings. However, the exemplary embodiments can be implemented in a variety of forms and should not be construed as being limited to the examples set forth herein. Rather, these embodiments are provided so that the present disclosure will be more thorough and complete, and the concepts of the exemplary embodiments are fully communicated to those skilled in the art. The same reference numerals in the figures indicate the same or similar structures, and thus the detailed descriptions thereof are omitted.

Although relative terms, such as “upper” and “lower”, are used in this specification to describe the relative relationship between one component of an icon and another component, these terms are used in this specification only for convenience, for example, according to the directions of the examples described in the drawings. It can be understood that if a device of an icon is turned over and inverted, an “upper” component will become a “lower” component. Other relative terms such as “high”, “low”, “top”, “bottom”, “left”, and “right” also have similar meanings. When a structure is located “on” other structures, it may mean that the structure is integrally formed on other structures, or the structure is “directly” disposed on other structures, or the structure is “indirectly” disposed on other structures through another structure.

The terms “one”, “a/an”, and “the” are used to indicate the presence of one or more elements/components/etc. The terms “including” and “having” are used in an open-type inclusive sense and mean that there may be additional elements/components/etc. in addition to the listed elements/components/etc.

A chip usually includes a plurality of cells. For example, a typical DRAM chip includes 64,000,000 memory cells, and these memory cells can be arranged in a manner of rows and columns to form a main array, so as to facilitate addressing through word lines and bit lines.

In the manufacturing process of the typical DRAM chip, there may be a million or even millions of cells in the main array which have defects, that is, the failure addresses. In order to improve the yield of the chip, redundant lines are usually manufactured on the chip, and these redundant lines can replace the failed lines where the defective failure addresses are located, thereby bypassing these defective failure addresses and allowing a memory circuit to be used normally.

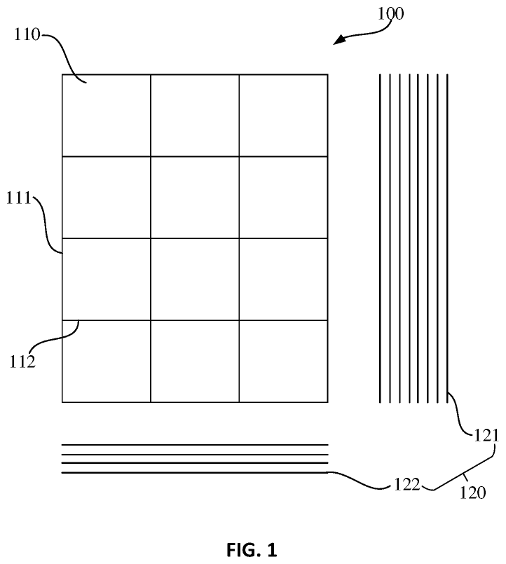

FIG. 1 shows a schematic structural diagram of a chip according to an exemplary embodiment of the present disclosure. A chip 100 usually includes a normal cell area 110 and a redundant cell area 120. The normal cell area 110 includes many cells. The normal cell area 110 includes two orthogonal lines: word lines 111 and bit lines 112. The word lines 111 are column lines, and the bit lines 112 are row lines. Furthermore, in addition to the normal cell area 110, the chip 100 is further provided with the redundant cell area 120 including redundant cells. The redundant cell area 120 includes two orthogonal straight lines: Redundant Word Lines (RWLs) 121 and Redundant Bit Lines (RBLs) 122. The RWLs 121 are column lines for repairing the failure addresses on the word lines 111. The RBLs 122 are row lines for repairing the failure addresses on the bit lines 112.

However, for a packaged memory after, when the number of the failed lines is greater than the number of the redundant lines in the memory, there are failed lines that cannot be repaired so that the information of the failure addresses cannot be read and programs cannot run normally. Based on this, this exemplary embodiment provides a post package repairing method for a memory.

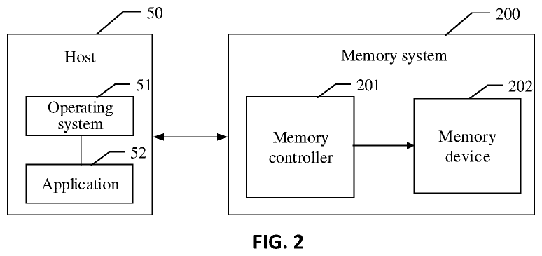

FIG. 2 shows a block diagram of a post package repairing system for a memory according to an exemplary embodiment of the present disclosure. As shown in FIG. 2, a memory system 200 executes at least a writing operation and a reading operation in response to various Input/Output (I/O) requests received from a host 50. The memory system 200 usually includes a memory controller 201 and a memory device 202.

The host 50 may be an electronic device, such as a computer, a notebook computer, a tablet computer, a smart phone, a smart television, etc. The host 50 can access the memory system 200 in conjunction with the execution of one or more applications 52 running one or more operating systems 51.

During the execution of a reading/writing operation or other memory access operations in response to host requests, the memory system 200 can provide a Post Package Repair (PPR) command and associated failure addresses from the memory controller 201 to the memory device 202.

Once a failure part of an integrated circuit is identified, the repair process includes replacing the failure part with a redundant resource. The method of replacing the failure part with the redundant resource is called a PPR method. The PPR includes hard Post Package Repair (hPPR) and soft Post Package Repair (sPPR). The sPPR is a method for quickly but temporarily repairing elements in a memory array. The hPPR needs a longer time, but can permanently repair the elements in the memory array.

In practical applications, for the sPPR or the hPPR, in a same bank group, usually only one redundant line (RBL or RWL) can perform a repair operation.

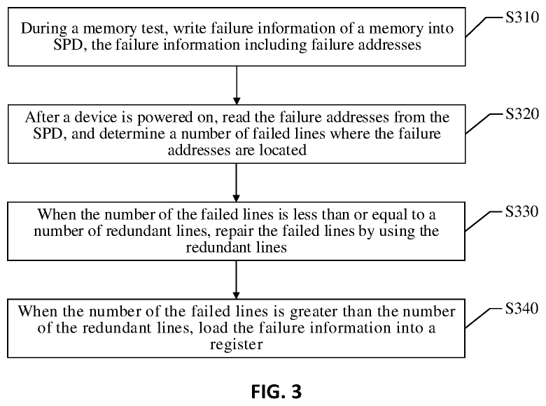

FIG. 3 schematically shows a flowchart of steps of a post package repairing method for a memory according to some embodiments of the present disclosure. Referring to FIG. 3, the post package repairing method for a memory may include the following operations.

In S310, during a memory test, failure information of the memory is written into the memory, and the failure information includes failure addresses.

In S320, after a device is powered on, the failure addresses are read from the memory, and a number of failed lines where the failure addresses are located is determined.

In S330, when the number of the failed lines is less than or equal to a number of redundant lines, the failed lines are repaired by using the redundant lines.

In S340, when the number of the failed lines is greater than the number of the redundant lines, the failure information is loaded into a register.

According to the post package repairing method for a memory in this exemplary embodiment, on the one hand, by writing the failure addresses of the memory into the SPD, after the device is powered on, the failure addresses can be directly read from the SPD, the number of the failed lines is also determined, and according to the number of the failed lines, the failed lines are repaired, or the failure information is loaded into the register, so that direct calling can be realized when needed, so as to realize the process of completely repairing the failure addresses. On the other hand, by recording the failure information during the memory test and repairing the failure addresses after the device is powered on, a way of repairing the failure addresses from the software level is realized, thereby providing an implementation scheme for repairing a packaged memory, reducing the failure rate of the memory, and prolonging the service life of the memory.

In the following, the post package repairing method for a memory in this exemplary embodiment will be further described.

In S310, during a memory test, failure information of the memory is written into SPD, and the failure information includes failure addresses.

The SPD is a set of configuration information about a memory module, such as the number of P-Banks (Physical Banks), the number of row addresses/column addresses, bit widths, and various main operation time sequences. These information are stored in an Electrically Erasable Programmable Read Only Memory (EEPROM) with a capacity of 256 bytes. That is, the time sequence information in the SPD is compiled by a module manufacturer according to the characteristics of the used memory chip and is written into the EEPROM, and the EEPROM is stored in the memory. In other words, the failure information may be written into the SPD of the EEPROM.

The main purpose of the EEPROM is to assist the Northbridge chip to accurately adjust the physical/time sequence parameters of the memory to achieve the best use effect. If the memory setting option is set to “By SPD” in a Basic Input Output System (BIOS), when the device is powered on, the Northbridge will automatically configure the corresponding memory time sequence and control register according to the parameter information in the SPD, so as to avoid faults due to manual adjustment errors.

In a memory access test process, the memory is tested first. This process is completed before the memory leaves the factory. The memory manufacturer uses testing software to implement the reading and writing tests of the memory, and the failure information is written into the SPD of the memory. As shown in Table 1, the SPD is defined as 512 Kb. Bytes 384 to 511 are defined by users, and the contents defined from Byte 384 are shown in Table 2. The failure addresses are written down according to this content format in sequence, as shown in Table 2.

TABLE 1

| | | | | | | | |
|---|---|---|---|---|---|---|---|
| Byte0 | Byte1 | Byte2 | Byte3 | Byte4 | Byte5 | Byte6 | Byte7 |
| Byte8 | Byte9 | Byte10 | Byte11 | Byte12 | Byte13 | Byte14 | Byte15 |
| Byte496 | Byte497 | Byte498 | Byte499 | Byte500 | Byte501 | Byte502 | Byte503 |
| Byte504 | Byte505 | Byte506 | Byte507 | Byte508 | Byte509 | Byte510 | Byte511 |

TABLE 2

| Byte | Information |
|---|---|
| 384 | Position and Rank of first failure particle in memory |
| 385 | Bank/Bank Group corresponding to first failure particle in memory |
| 396 | Row address corresponding to first failure particle in memory |
| 397 | Column address of first failure particle in memory |
| 398 | Position and Rank of second failure particle in memory |
| 399 | Bank/Bank Group corresponding to second failure particle in |
| | memory |
| 400 | Row address corresponding to second failure particle in memory |
| 401 | Column address of second failure particle in memory |

In Table 2, the failure information, such as the failure positions of all failure particles, the Rank and Bank/Bank Group of failure particles, row addresses and column addresses in the memory, may be written into the user-defined bytes of the memory. The Rank refers to a memory block on a memory module. An array for addressing in a memory chip is called the Bank of the memory chip.

In practical applications, the memory information may be written into the user-defined bytes according to the failure information sequence in Table 2, or may be written in other sequences, which is not limited in this exemplary embodiment.

In S320, after the device is powered on, the failure addresses are read from the SPD, and a number of failed lines where the failure addresses are located is determined.

In this exemplary embodiment, after the memory manufacturer completes the step of writing the failure information, the system of the device is powered on. For example, in the using process of a user, a Central Processing Unit (CPU) of an operating system will first read the SPD in the memory, determine the number of the failed lines where the failure addresses are located according to the failure addresses recorded in the SPD, and determine different repair schemes according to different numbers of the failed lines.

Since redundant lines in a same bank group can only repair the failed lines in the bank group, the determining the number of the failed lines where the failure addresses are located may include determining, in a same bank group, the number of the failed lines where the failure addresses are located.

In S330, when the number of the failed lines is less than or equal to the number of the redundant lines, the failed lines are repaired by using the redundant lines. In S340, when the number of the failed lines is greater than the number of the redundant lines, the failure information is loaded into the register.

In this exemplary embodiment, a specific repair scheme is determined by comparing the number of the failed lines with the number of the redundant lines. In a case that the number of the failed lines is less than or equal to the number of the redundant lines, the failed lines can be repaired directly by using the redundant lines. The repair here may be hPPR or sPPR.

Specifically, when the failed lines are stored in a non-volatile memory, an hPPR command is used for repairing; and when the failed lines are stored in a volatile memory, an sPPR command is used for repairing. The hPPR is a permanent repair method. After the hPPR is used for repairing, the redundant lines permanently replace the failed lines.

In a case that the number of the failed lines is greater than the number of the redundant lines, the failure information is directly loaded into the register to temporarily store the failure information. In this way, during reading and writing access to the memory, if the failure addresses are accessed, the information corresponding to the failure addresses is directly read and written from the register, thereby avoiding faults caused by directly accessing the failure addresses.

It should also be noted that the number of the redundant lines also refers to the number of the redundant lines in the same bank group.

In this exemplary embodiment, through the S320 to the S340, the memory can be repaired after the device is powered on every time to realize a method for repairing the memory from the software level, so that a user can repair the memory during the use of the memory to reduce the failure rate during the use of the memory so as to improve the user experience.

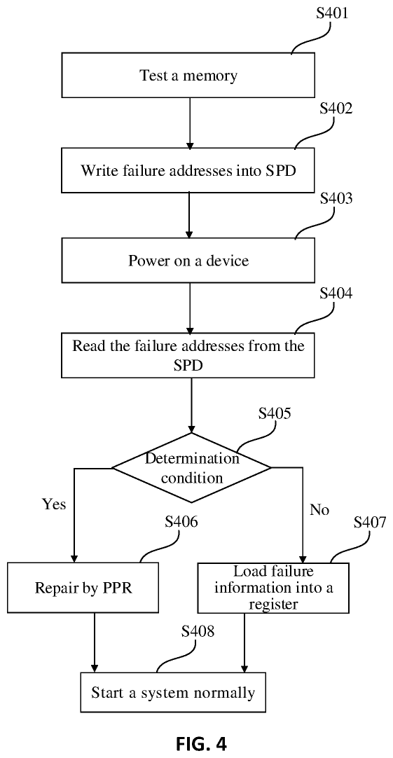

FIG. 4 schematically shows a flowchart of a post package repairing process according to an exemplary embodiment of the present disclosure. As shown in FIG. 4, in S401, the memory is tested to obtain failure addresses of the memory; in S402, the failure addresses are written into the SPD; in S403, the device is powered on; in S404, the failure addresses are read from the SPD; in S405, a determination condition is performed, that is, whether the number of the failed lines where the failure addresses are located is less than or equal to the number of the redundant lines is judged; if the determination condition is met, the S406 is executed: the PPR is used for repairing; if the determination condition is not met, the S407 is executed: the failure information is loaded into the register; and after the repair of all failure addresses is completed, the S408 is executed: the system is started normally. Furthermore, during reading and writing access to the memory, if the failure addresses are accessed, the information corresponding to the failure addresses is directly read and written from the register.

It should be noted that although the steps of the method in the disclosure are described in a specific sequence in the drawings, this does not require or imply that these steps must be performed in the specific sequence, or that all the steps shown must be performed to achieve the desired result. Additionally or alternatively, some steps may be omitted, multiple steps may be combined into one step to be executed, and/or one step may be divided into multiple steps to be executed.

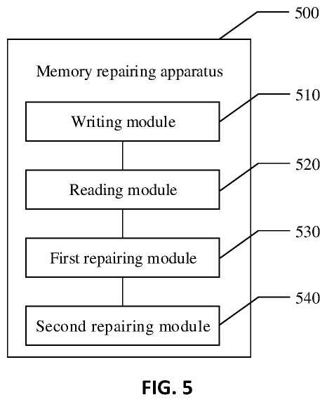

In addition, in this exemplary embodiment, a post package repairing apparatus for a memory is further provided. Referring to FIG. 5, a post package repairing apparatus 500 for a memory may include: a writing circuit 510, a reading circuit 520, a first repairing circuit 530 and a second repairing circuit 540.

The writing circuit 510 is configured to write failure information of the memory into the memory during a memory test, and the failure information includes failure addresses.

The reading circuit 520 is configured to read the failure addresses from the memory and determine a number of failed lines where the failure addresses are located after a device is powered on.

The first repairing circuit 530 is configured to repair the failed lines by using redundant lines when the number of the failed lines is less than or equal to the number of the redundant lines.

The second repairing circuit 540 is configured to load the failure information into a register when the number of the failed lines is greater than the number of the redundant lines.

In this exemplary embodiment, the writing circuit 510 can write the failure information, such as the failure positions of all failure particles, the Rank and Bank/Bank Group of failure particles, row addresses and column addresses in the memory, into the user-defined bytes of the memory. The above memory information can be written into the user-defined bytes in sequence.

The reading circuit 520 is configured to first read SPD in an EEPROM after the system of the device is powered on, determine the number of the failed lines where the failure addresses are located according to the failure addresses recorded in the SPD, and determine different repair schemes according to different numbers of the failed lines.

Since redundant lines in a same bank group can only repair the failed lines in the bank group, the determining the number of the failed lines where the failure addresses are located may include determining, in a same bank group, the number of the failed lines where the failure addresses are located.

By comparing the number of the failed lines with the number of the redundant lines in the same bank group, the first repairing circuit 530 or the second repairing circuit 540 is used for repairing. In a case that the number of the failed lines is less than or equal to the number of the redundant lines, the first repairing circuit 530 can repair the failed lines directly by using the redundant lines. The repair here may be hPPR or sPPR.

In a case that the number of the failed lines is greater than the number of the redundant lines, the second repairing circuit 540 can load the failure information directly into the register to temporarily store the failure information. In this way, during reading and writing access to the memory, if the failure addresses are accessed, information corresponding to the failure addresses is directly read and written from the register, thereby avoiding faults caused by directly accessing the failure addresses.

In this exemplary embodiment, through the writing circuit 510, the reading circuit 520, the first repairing circuit 530 and the second repairing circuit 540, the memory can be repaired after the device is powered on every time to realize a method for repairing the memory from the software level, so that a user can repair the memory during the use of the memory to reduce the failure rate during the use of the memory so as to improve the user experience.

It should be noted that although several modules or units of the post package repairing apparatus for a memory are mentioned in the above detailed description, this division is not mandatory. In fact, according to the embodiments of the present disclosure, the features and functions of two or more modules or units described above may be embodied in one module or unit. Conversely, the features and functions of one module or unit described above may be further divided into a plurality of modules or units to be embodied.

In addition, the above drawings are merely schematic illustrations of the processes included in the method according to the exemplary embodiments of the disclosure, but are not intended for limitation. It is easy to understand that the processes shown in the above drawings do not indicate or limit the time sequence of these processes. In addition, it is also easy to understand that these processes may be executed synchronously or asynchronously in multiple modules.

In the exemplary embodiments of the present disclosure, an electronic device capable of implementing the above method is further provided.

Those skilled in the art can understand that various aspects of the disclosure can be implemented as systems, methods, or program products. Therefore, various aspects of the disclosure can be specifically implemented in the following forms: a complete hardware implementation manner, a complete software implementation manner (including firmware, micro-codes, etc.), or a hardware and software combined implementation manner, which may be collectively known as “circuits”, “modules” or “systems”.

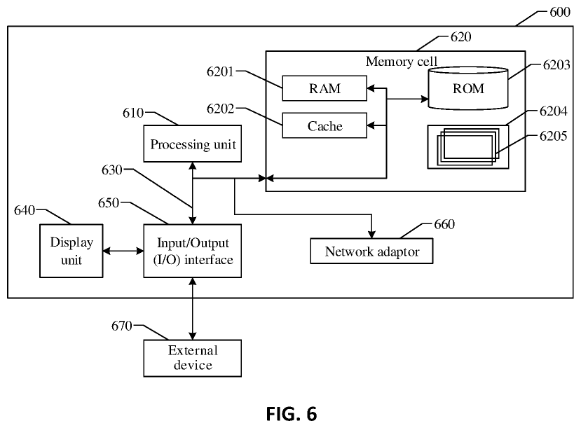

An electronic device 600 according to this implementation manner of the disclosure will be described below with reference to FIG. 6. The electronic device 600 shown in FIG. 6 is only an example, and should not bring any limitation to the function and application scope of the embodiments of the disclosure.

As shown in FIG. 6, the electronic device 600 is represented in the form of a general-purpose computing device. The components of the electronic device 600 may include, but are not limited to: at least one processing unit 610, at least one memory cell 620, a bus 630 connected with different system components (including the memory cell 620 and the processing unit 610), and a display unit 640.

The memory cell 620 stores program codes, and the program codes can be executed by the processing unit 610, so that the processing unit 610 executes the steps according to various exemplary embodiments of the disclosure described in the above “exemplary method” of this specification. For example, the processing unit 610 can execute the steps shown in FIG. 3: in S310, during a memory test, the failure information of the memory is written into the SPD, and the failure information includes failure addresses; in S320, after the device is powered on, the failure addresses are read from the SPD, and a number of failed lines where the failure addresses are located is determined; in S330, when the number of the failed lines is less than or equal to the number of the redundant lines, the failed lines are repaired by using the redundant lines; and in S340, when the number of the failed lines is greater than the number of the redundant lines, the failure information is loaded into the register.

The memory cell 620 may include a readable medium in the form of a volatile memory cell, such as a Random Access Memory (RAM) cell 6201 and/or a cache memory cell 6202, and may further include a Read Only Memory (ROM) cell 6203.

The memory cell 620 may also include a program/utility tool 6204 having a set of (at least one) program module 6205. Such program module 6205 includes, but is not limited to: an operating system, one or more application programs, and other program modules and program data. One or a certain combination of these examples may include the implementation of a network environment.

The bus 630 may represent one or more of several types of bus structures, including a memory cell bus or a memory cell controller, a peripheral bus, an accelerated graphics port, a processing unit, or a local bus using any of a variety of bus structures.

The electronic device 600 may also communicate with one or more external devices 670 (such as keyboards, pointing devices, Bluetooth devices, etc.), may also communicate with one or more devices that enable a user to interact with the electronic device 600, and/or may also communicate with any device (such as a router, a modem, etc.) that enables the electronic device 600 to communicate with one or more other computing devices. Such communication may be performed through an Input/Output (I/O) interface 650. Furthermore, the electronic device 600 may also communicate with one or more networks (such as a Local Area Network (LAN), a Wide Area Network (WAN) and/or a public network such as the Internet) through a network adaptor 660. As shown in the figure, the network adaptor 660 communicates with other modules of the electronic device 600 through the bus 630. It should be understood that although not shown in the figure, other hardware and/or software modules may be used in conjunction with the electronic device 600, including but not limited to: micro-codes, device drivers, redundant processing units, external disk drive arrays, RAID systems, magnetic tape drivers, data backup memory systems, etc.

Through the description of the above embodiments, those skilled in the art can easily understand that the exemplary embodiments described here may be implemented by software, or may be implemented by combining software with necessary hardware. Therefore, the technical solution according to the embodiments of the present disclosure may be embodied in the form of a software product. The software product may be stored in a nonvolatile storage medium (such as a CD-ROM, a U disk, a mobile hard disk, etc.) or on a network, and includes several instructions to enable a computing device (such as a personal computer, a server, a terminal device, a network device, etc.) to execute the method according to the embodiments of the present disclosure.

In the exemplary embodiments of the present disclosure, a computer-readable storage medium is further provided. Program products capable of implementing the above method of this specification are stored on the computer-readable storage medium. In some possible embodiments, various aspects of the disclosure may also be implemented in the form of a program product, including program codes. When the program product runs on the terminal device, the program codes are used to make the terminal device execute the steps according to various exemplary embodiments of the disclosure described in the above “exemplary method” of this specification.

The program product used to implement the above method according to the embodiments of the disclosure may adopt a portable Compact Disk Read Only Memory (CD-ROM), includes program codes, and may run on a terminal device, such as a personal computer. However, the program product of the disclosure is not limited thereto. In this document, the readable storage medium may be any tangible medium that contains or stores programs, and the programs may be used by or in combination with an instruction execution system, apparatus, or device.

The program product may use any combination of one or more readable media. The readable medium may be a readable signal medium or a readable storage medium. The readable storage medium may be, but is not limited to, an electrical, magnetic, optical, electromagnetic, infrared, or semiconductor system, apparatus or device, or a combination of any of the above. More specific examples (non-exhaustive list) of the readable storage medium include: an electrical connector with one or more wires, a portable disk, a hard disk, an RAM, an ROM, an EPROM or a flash memory, an optical fiber, a portable CD-ROM, an optical storage device, a magnetic storage device, or any suitable combination of the above.

The computer-readable signal medium may include a data signal propagated in a base band or as a part of a carrier, and readable program codes are carried therein. This propagated data signal may take many forms, including but not limited to an electromagnetic signal, an optical signal, or any suitable combination of the above. The readable signal medium may also be any readable medium other than the readable storage medium. The readable medium may send, propagate, or transmit the programs used by or in combination with an instruction execution system, apparatus, or device.

The program codes contained on the readable medium may be transmitted by any suitable medium, including but not limited to a wireless medium, a wired medium, an optical cable, a Radio Frequency (RF) medium, etc., or any suitable combination of the above.

The program codes for performing the operations of the disclosure may be written in any combination of one or more programming languages. The programming languages include object-oriented programming languages such as Java, C++, etc., and further include conventional procedural programming languages such as “C” language or similar programming languages. The program codes may be completely executed on a users computing device, partially executed on a user device, executed as an independent software package, partially executed on a users computing device and partially executed on a remote computing device, or completely executed on a remote computing device or a server. In the situation involving a remote computing device, the remote computing device may be connected to a users computing device through any type of network, including an LAN or a WAN, or may be connected to an external computing device (via the Internet by means of an Internet service provider, for example).

In addition, the above drawings are merely schematic illustrations of the processes included in the method according to the exemplary embodiments of the disclosure, but are not intended for limitation. It is easy to understand that the processes shown in the above drawings do not indicate or limit the time sequence of these processes. In addition, it is also easy to understand that these processes may be executed synchronously or asynchronously in multiple modules.

Other embodiments of the present disclosure will be apparent to those skilled in the art from consideration of the specification and practice of the disclosure here. This application is intended to cover any variations, uses, or adaptive changes of the present disclosure. These variations, uses, or adaptive changes follow the general principles of the present disclosure and include common general knowledge or conventional technical means in the technical field, which are not disclosed herein. The specification and embodiments are only regarded as exemplary, and the true scope and spirit of the present disclosure are indicated by claims.

It should be understood that the present disclosure is not limited to the exact construction that has been described above and illustrated in the accompanying drawings, and that various modifications and changes can be made without departing from the scope thereof. The scope of the present disclosure is limited only by the appended claims.

1. A post package repairing method for a memory, comprising:
during a memory test, writing failure information of the memory into the memory, the failure information comprising failure addresses;
after a device is powered on, reading the failure addresses from the memory, and determining a number of failed lines where the failure addresses are located;
when the number of the failed lines is less than or equal to a number of redundant lines, repairing the failed lines by using the redundant lines; and
when the number of the failed lines is greater than the number of the redundant lines, loading the failure information into a register.

2. The method of claim 1, wherein writing failure information of the memory into the memory comprises:
writing the failure information into Serial Presence Detect (SPD) of an Electrically Erasable Programmable Read Only Memory (EEPROM).

3. The method of claim 1, wherein determining the number of failed lines where the failure addresses are located comprises:
determining, in a same bank group, the number of the failed lines where the failure addresses are located.

4. The method of claim 3, wherein the number of the redundant lines is the number of redundant lines in the same bank group.

5. The method of claim 1, further comprising:
during reading and writing access to the memory, if the failure addresses are accessed, directly reading and writing information corresponding to the failure addresses from the register.

6. The method of claim 1, wherein during the memory test, writing failure information of the memory into the memory comprises:
during the memory test, writing the failure information into user-defined bytes of the memory.

7. The method of claim 1, wherein the failure information further comprises failure positions, and Rank, Bank/Bank Group, row addresses and column addresses of failure particles; and
writing the failure information into user-defined bytes of the memory comprises:
writing the failure information into the user-defined bytes in sequence.

8. A post package repairing apparatus for a memory, comprising:
a writing circuit configured to write failure information of the memory into the memory during a memory test, the failure information comprising failure addresses;
a reading circuit configured to read the failure addresses from Serial Presence Detect (SPD) and determine a number of failed lines where the failure addresses are located after a device is powered on;
a first repairing circuit configured to repair the failed lines by using redundant lines when the number of the failed lines is less than or equal to a number of the redundant lines; and
a second repairing circuit configured to load the failure information into a register when the number of the failed lines is greater than the number of the redundant lines.

9. The apparatus of claim 8, wherein writing failure information of the memory into the memory comprises:
writing the failure information into Serial Presence Detect (SPD) of an Electrically Erasable Programmable Read Only Memory (EEPROM).

10. The apparatus of claim 8, wherein determining the number of failed lines where the failure addresses are located comprises:
determining, in a same bank group, the number of the failed lines where the failure addresses are located.

11. The apparatus of claim 10, wherein the number of the redundant lines is the number of redundant lines in the same bank group.

12. The apparatus of claim 8, further comprising:
a reading and writing circuit configured to directly read and write information corresponding to the failure addresses from the register if the failure addresses are accessed during reading and writing access to the memory.

13. The apparatus of claim 8, wherein during the memory test, writing failure information of the memory into the memory comprises:
during the memory test, writing the failure information into user-defined bytes of the memory.

14. The apparatus of claim 8, wherein the failure information further comprises Rank, Bank/Bank Group, row addresses and column addresses of failure particles; and
writing the failure information into user-defined bytes of the memory comprises:
writing the failure information into the user-defined bytes in sequence.

15. A non-transitory computer-readable storage medium having stored thereon computer-executable instructions that, when executed by a processor, cause the processor to perform operations of:
during a memory test, writing failure information of memory into the memory, the failure information comprising failure addresses;
after a device is powered on, reading the failure addresses from the memory, and determining a number of failed lines where the failure addresses are located;
when the number of the failed lines is less than or equal to a number of redundant lines, repairing the failed lines by using the redundant lines; and
when the number of the failed lines is greater than the number of the redundant lines, loading the failure information into a register.

16. An electronic device, comprising:
a processor; and
a memory configured to store one or more programs that, when executed by the processor, cause the processor to perform the post package repairing method for a memory according to claim 1.
